(19) United States
(12) Patent Application Publication
(10) Pub. No.: US 2012/0224734 A1
(43) Pub. Date: Sep. 6, 2012

(54) HEARING AID AND METHOD OF FABRICATING THE SAME

(75) Inventor: Avi Cohen, Nes Ziona (IL)

(73) Assignee: Objet Ltd., Rechovot (IL)

(21) Appl. No.: 13/508,558

(22) PCT Filed: Nov. 8, 2010
(86) PCT No.: PCT/IL10/00921

§ 371 Date: May 8, 2012

Related U.S. Application Data
(60) Provisional application No. 61/259,177, filed on Nov. 8, 2009.

(51) Int. Cl. H04R 25/00; H05K 13/00; B05D 5/00

(52) U.S. Cl. 381/322; 427/256; 29/592.1

(57) ABSTRACT

A casing device for a hearing aid is disclosed. The casing device comprises an elongated extension fabricated by solid freeform fabrication and being adapted to fit within the auditory canal of a wearer. The casing device has at least two regions each being characterized by a different hardness. The casing device is configured to receive and encapsulate an electroacoustic device.

### RELATED APPLICATION

This application claims the benefit of priority from U.S. Provisional Application No. 61/259,177 filed Nov. 8, 2009, the contents of which are hereby incorporated by reference as if fully set forth herein.

### FIELD AND BACKGROUND OF THE INVENTION

The present invention, in some embodiments thereof, relates to a hearing aid and, more particularly, but not exclusively, to an in-the-canal hearing aid fabricated by Solid Freeform Fabrication.

Numerous types and designs of hearing aids for assisting persons with hearing deficiencies are known. Typically, hearing aids incorporate a microphone for converting sound waves to electrical signals. These signals are then amplified by an amplifier circuit and sent to a receiver. The receiver converts the electrical signals into amplified sound waves and directs the sound waves toward the eardrum.

Old designs of hearing aids included a bulky protrusion from the ear, noticeable by all, indicating that the patient or user wears a hearing aid. Later modifications relocated the controls which protruded from the ear to a position in back of the ear. Attempts to overcome the outward extending controls included the creation of custom molded in-the-canal hearing aids. Many hearing aids today are created by this custom molding method or process by which a soft silicone or similar ear impression material is used to take an impression of the wearer's ear canal which is then used to create a hard plastic casing for a hearing aid which conforms to the wearer's ear.

In-the-canal type hearing aids are made possible because of the miniaturization of batteries and necessary electronic components. These miniaturized components are incorporated into a single ear mold to be worn in the external ear, extending or penetrating into the auditory canal of a user. Locating the hearing aid in the ear, rather than on the belt or behind the ear, is preferred for acoustic reasons. Another advantage of this type of hearing aid is derived from its small size and, therefore, its inconspicuous cosmetic appearance.

Individual fitting of the ear mold requires that an impression be made of the individual user's ear during a preliminary visit to the audiologist or hearing aid dispenser. The impression is sent to a craftsman for individual molding of the ear casing to match the user's right and/or left auditory canals. These molds are then assembled with predetermined electronic components at the factory and fitted in the user's ears during a subsequent visit to the dispenser's office. In addition to the need for at least one subsequent visit, this method is uncomfortable because of the necessity of making an ear impression. The method is also expensive and time consuming due to the shipping, handling and individual craftsmanship required in production of each individual ear mold.

Also known are stock canal aids which conform to standard requirements for mass production of hearing aids. Such aids typically have cylindrical or elliptical shape, so that the right and left ear molds were symmetrical and interchangeable. Recently, stock canal ear molds have added a single rearward bend to the basically cylindrical or elliptical shape of the ear mold casing. In these designs, the same casing can be used for the right and left canals by inverting the casing before adding the cover plate. An oversized cover plate with adjustable volume control and electronic components are attached to the casing. The periphery of the cover plate is then carved down and buffed to match the casing. The result is symmetrical right and left ear molds that are unique due to the different directions of volume control in the left ear mold and right ear mold.

Most in-the-canal hearing aids are embodied within a hard plastic casing. Some designs include a soft tip to facilitate the insertion of the hard plastic casing into the ear and to improve sealing thereby allowing higher amplification of the sound without reaching acoustic feedback.

Several types of hearing aids are disclosed in U.S. Pat. Nos. 5,825,896, 5,636,285, 4,918,757, 4,471,490 and 3,852,540.

### SUMMARY OF THE INVENTION

According to an aspect of some embodiments of the present invention there is provided a casing device for a hearing aid. The casing device comprises an elongated extension fabricated by solid freeform fabrication and being adapted to fit within the auditory canal of a wearer. The casing device has at least two regions each being characterized by a different hardness. The casing device is configured to receive and encapsulate an electroacoustic device.

According to some embodiments of the invention the casing device comprises a gradient region between the at least two regions, the gradient region being characterized by a gradually increasing hardness.

According to some embodiments of the invention a frontal section at a tip of the elongated extension has a reduced hardness compared to at least one other region of the elongated extension.

According to some embodiments of the invention the casing device comprises an upper contact section at an upper part of the elongated extension to engage an upper surface of the auditory canal, the upper contact section having a reduced hardness compared to at least one other region of the elongated extension.

According to some embodiments of the invention the casing device comprises a base section from which the elongated extension is extending, the base section having an increased hardness compared to at least one other region of the elongated extension.

According to some embodiments of the invention the casing device comprises an inner layer and an outer contact layer covering the inner layer, the outer contact layer having a reduced hardness compared to the inner layer.

According to some embodiments of the invention the casing device comprises a frontal section at a frontal part of the elongated extension, a base section from which the elongated extension is extending, and an intermediate section between the frontal section and the base section, the intermediate section having a reduced hardness compared to both the frontal section and the base section.

According to some embodiments of the invention the casing device comprises a flexible relief pattern at a tip of the elongated extension.

According to some embodiments of the invention the casing device has a skin-like color.

According to some embodiments of the invention the casing device comprises at least one region made of a flexible material.

According to an aspect of some embodiments of the present invention there is provided a hearing aid device. The hearing aid device comprises a casing device as described herein, and an electroacoustic device encapsulated by the casing device.

According to an aspect of some embodiments of the present invention there is provided a method of improving hearing of a hearing impaired individual. The method comprises introducing the hearing aid device to the ear of the individual. In some embodiments of the present invention the method comprises introducing another hearing aid device of similar properties to the other ear of the individual.

According to an aspect of some embodiments of the present invention there is provided a method of fabricating a casing of a hearing aid device. The method comprises using a solid freeform fabrication apparatus and at least two building materials for fabricating a casing having an elongated extension adapted to fit within the auditory canal of a wearer. The fabrication comprises forming at least two regions each being characterized by a different hardness.

According to some embodiments of the invention the solid freeform fabrication apparatus is a three-dimensional printing apparatus.

According to some embodiments of the invention the method comprises forming a gradient region between the at least two regions, the gradient region being characterized by a gradually increasing hardness.

According to some embodiments of the invention the method comprises forming a frontal section at a tip of the elongated extension, the frontal section having a reduced hardness compared to at least one other region of the elongated extension.

According to some embodiments of the invention the method comprises forming an upper contact section at an upper part of the elongated extension to engage an upper surface of the auditory canal, the upper contact section having a reduced hardness compared to at least one other region of the elongated extension.

According to some embodiments of the invention the method comprises forming a base section from which the elongated extension is extending, the base section having an increased hardness compared to at least one other region of the elongated extension.

According to some embodiments of the invention the method comprises forming an inner layer and an outer contact layer covering the inner layer, the outer contact layer having a reduced hardness compared to the inner layer.

According to some embodiments of the invention the method comprises forming a frontal section at a frontal part of the elongated extension, a base section from which the elongated extension is extending and an intermediate section between the frontal section and the base section, the intermediate section having a reduced hardness compared to both the frontal section and the base section.

According to some embodiments of the invention the method comprises forming a flexible relief pattern at a tip of the elongated extension.

According to some embodiments of the invention the flexible relief pattern comprises a plurality of protuberances.

According to some embodiments of the invention the flexible relief pattern comprises at least one ring wound around the elongated extension.

According to some embodiments of the invention at least one of the building materials has a skin-like color.

According to some embodiments of the invention the method comprises forming at least one region made of a flexible material.

According to an aspect of some embodiments of the present invention there is provided a method of manufacturing a hearing aid device. The method comprises fabricating a casing device using a method as described herein and encapsulating an electroacoustic device within the casing device.

Unless otherwise defined, all technical and/or scientific terms used herein have the same meaning as commonly understood by one of ordinary skill in the art to which the invention pertains. Although methods and materials similar or equivalent to those described herein can be used in the practice or testing of embodiments of the invention, exemplary methods and/or materials are described below. In case of conflict, the patent specification, including definitions, will control. In addition, the materials, methods, and examples are illustrative only and are not intended to be necessarily limiting.

### BRIEF DESCRIPTION OF THE DRAWINGS

Some embodiments of the invention are herein described, by way of example only, with reference to the accompanying drawings and images. With specific reference now to the drawings in detail, it is stressed that the particulars shown are by way of example and for purposes of illustrative discussion of embodiments of the invention. In this regard, the description taken with the drawings makes apparent to those skilled in the art how embodiments of the invention may be practiced.

In the drawings:

FIG. 1 is a schematic illustration of a cross-sectional view of an ear and a hearing aid device placed therein according to some exemplary embodiments of the present invention;

FIG. 2 is an image of a perspective view of a casing device for encapsulating a hearing aid, in an embodiment of the present invention in which a frontal section at a tip of the casing is characterized by a reduced hardness compared to other sections of the casing;

FIGS. 3A-C are schematic illustrations of a casing device for encapsulating a hearing aid, in embodiments of the invention in which the casing device comprises a gradient region between at least two regions;

FIG. 4 is an image of a perspective view of a casing device for encapsulating a hearing aid, in an embodiment of the present invention in which the casing device has an upper contact section to engage an upper surface of the auditory canal wherein the upper contact section has a reduced hardness compared to at least one other region of the casing device;

FIGS. 5A-B are a schematic illustration of a cross-sectional view (FIG. 5A) and an image of a perspective view (FIG. 5B) of a casing device for encapsulating a hearing aid, in an embodiment of the invention in which the casing device has an inner layer and an outer contact layer covering the inner layer;

FIG. 6 is an image of a perspective view of a casing device for encapsulating a hearing aid, in an embodiment of the present invention in which the casing device has a frontal section, a base section and an intermediate section between the frontal section and the base section, wherein the intermediate section has a reduced hardness compared to both the frontal section and the base section; and

FIGS. 7A-B are images of perspective views of casing devices for encapsulating a hearing aid, in embodiments of the present invention in which the casing devices have a flexible relief pattern at a tip of the casing.

### DESCRIPTION OF SPECIFIC EMBODIMENTS OF THE INVENTION

The present invention, in some embodiments thereof, relates to a hearing aid and, more particularly, but not exclusively, to an in-the-canal hearing aid fabricated by Solid Freeform Fabrication.

Before explaining at least one embodiment of the invention in detail, it is to be understood that the invention is not necessarily limited in its application to the details of construction and the arrangement of the components and/or methods set forth in the following description and/or illustrated in the drawings and/or the Examples. The invention is capable of other embodiments or of being practiced or carried out in various ways.

While conceiving the present invention it has been hypothesized and while reducing the present invention to practice it has been realized that the advantages of Solid Freeform Fabrication (SFF) can be exploited for fabricating a casing device for a hearing aid.

SFF is a technology enabling fabrication of arbitrarily shaped objects directly from computer data via additive formation steps. The basic operation of any SFF system consists of slicing a three-dimensional computer model into thin cross sections, translating the result into two-dimensional position data and feeding the data to control equipment which fabricates a three-dimensional structure in a layer-wise manner by forming a plurality of layers in a configured pattern corresponding to the shape of the objects.

In some embodiments of the present invention the SFF comprises three-dimensional printing. In these embodiments a building material is dispensed from a dispensing head having a set of nozzles to deposit layers on a supporting structure. Depending on the building material, the layers may then be cured or solidified using a suitable device. The material deposition and solidification is repeated layer by layer to form a 3D object. All these operations are well-known to those skilled in the art of solid freeform fabrication The building material of the present invention, however, comprises one or more, preferably at least two modeling materials, which form the casing, and one or more support materials which support the casing as it is being built. In one embodiment, the support material may be included with one or more modeling materials to form part of the casing. Alternatively, one or more of the modeling materials may be included together with the support material in the formation of a support structure for the casing being built.

Three-dimensional printing techniques suitable for the present embodiments are described in U.S. Pat. Nos. 6,259,962, 6,569,373, 6,658,314, 6,850,334, 7,183,335, 7,209,797, 7,225,045, 7,300,619, 7,479,510, 7,599,846, 7,685,694 and US Patent Publication No. US 2010/0191360, all of the same Assignee, the contents of which are hereby incorporated by reference. Preferably, the technique/s disclosed in U.S. Pat. Nos. 7,300,619 and/or 7,685,694 and/or U.S. Patent Publication No. 2010/0191360 are employed for fabricating the casing device of the invention.

In various exemplary embodiments of the invention the casing device is fabricated by dispensing two or more different modeling materials from different dispensing heads. The materials are optionally and preferably deposited in layers during the same pass of the printing heads. The materials and combination of materials are selected according to the desired properties of the casing device. Optionally and preferably, the materials and SFF protocol are selected so as to form a casing device having at least two regions, each being characterized by a different mechanical property, particularly a different hardness. For example, one region may be hard, i.e., having greater hardness, and another region may be soft and/or flexible, i.e., having reduced hardness.

As used herein, the term “hardness” refers to a property of a solid region which expresses the resistance of the region to indentation, scratching or abrasion. The hardness has a numerical value which can be measured, for example, by a durometer.

Typically, the hardness of the region is similar to the hardness of the material from which the region is made. However, this need not necessarily be the case, since, in some embodiments a region is formed of a combination of materials (e.g., two or more materials interlaced within layers of the region), in which case the hardness of the region is the effective hardness of all the materials forming the region, namely the resistance of the combination of materials to indentation, scratching or abrasion.

A “region” of the casing device of the present embodiments can be a region surrounding the device and having a surface which is exposed to the environment or a region having a surface that is covered by another modeling material or combination of modeling materials and is therefore not exposed to the surrounding environment. These types of regions are referred to as “outer region” and “inner region”, respectively. In use, an outer region can, therefore, contact the skin of the wearer, while an inner region is always separated from the skin by an outer region or part thereof.

When two regions have an inner-outer relationship, namely when the outer region is between the surrounding environment and the inner region, they form a layered structure in the thickness direction of the casing device.

The term “thickness direction” refers to a direction generally perpendicular to the outer surface of the casing wall. The thickness direction is thus the direction along which the thickness of the casing wall is measured.

The aforementioned layered structure can extend over the entire surface of the casing or it can be occupy only a section of the casing, while other sections may be devoid of inner regions. The layers of such layered structure should not be confused with the layer-wise manner by which the casing is formed (by virtue of the SFF technique). While the former corresponds to layers arranged in the thickness direction, the latter corresponds to layers arranged in the growth-direction, which is predominantly in a tangential direction to the outer surface of the casing. The two types of layers are distinguishable from one another also by their dimension. Growth-direction layers are typically much thinner, corresponding more or less to two dimensional cross-sections of the model of the casing, than thickness-direction layers. Typically, a growth-direction layer is about 10 times thinner than a thickness direction layer. For example, a thickness of a growth-direction layer can be from about 10 to about 40 microns, or from about 15 to about 30 microns, and a thickness of a thickness-direction layer can be from about 100 to about 500 microns, or from about 250 to about 350 microns.

In some embodiments of the present invention the casing has two or more outer regions each being characterized by a different hardness, and in some embodiments, the casing has at least one inner region and at least one outer region each being characterized by a different hardness.

In various exemplary embodiments of the invention the hardness of one of the regions of the casing is greater than the hardness of another region of the casing by at least 30 or at least 50 or at least 70 units on a durometer A hardness scale. Throughout this specification, a unit on a durometer A hardness scale is abbreviated as a “hardness unit.”

It is recognized that when the hardness of two materials is significantly different, their hardness values can be expressed using different the durometer hardness scales. For example, for materials that are relatively stiff, the hardness is typically expressed in terms of the durometer D scale, while for materials which are softer, e.g., rubber-like materials, the hardness is typically expressed in terms of the durometer A scale. Nevertheless, a person having ordinary skill in the art of material science would know how to determine the difference in hardness between two materials even when those materials are typically characterized using different durometer scales. For example, the ordinarily skilled person would know that the difference between a material having a hardness value of, say, 30 units on the durometer A hardness scale, and a material having a hardness value of, say, 80 units on the durometer D hardness scale, is more than 70 units on the durometer A hardness scale. In any event, the hardness value of the two materials in question can be measured directly using the same durometer type, as known in the art, so as to determine the hardness difference on the same durometer hardness scale.

In some embodiments of the present invention, the casing device comprises at least one region having a hardness of from about 25 to about 30 units on a durometer A hardness scale, and at least one region having a hardness of from about 80 to about 90 units on a durometer D hardness scale.

There are many advantages of having regions of different hardness.

A first advantage relates to the comfort of the wearer. For example, regions of the casing device which are in direct contact with the skin and are thus more likely to cause irritation to the skin of the ear or auditory canal are preferably characterized by a reduced hardness.

A second advantage relates to the affixation of the hearing aid within the ear of the wearer. Use of regions of different hardness in accordance with some embodiments of the present invention facilitates better affixation. It was recognized by the present inventor that different parts of the ear slightly move in relative motion from one another, e.g., during talking, chewing, or teeth clenching. To allow affixation of the hearing aid device during such relative motion, the casing device optionally and preferably has one or more regions of reduced hardness, e.g. a flexible region, at connective sections which are fabricated to be placed between ear parts that are expected to move with respect to one another. Additionally or alternatively, one or more sections of the casing device, preferably including a section that is to be placed more deeply in the ear (e.g., in the auditory canal), are provided with a flexible relief pattern. The relief pattern forms a region of reduced hardness compared to the surface underlying or adjacent to the pattern.

A third advantage relates to the process of introducing the hearing aid device into the ear. To ease this process, the tip of the casing device optionally and preferably has reduced hardness. The tip “guides” the other sections of the casing device while being introduced into the ear, and its reduced hardness allows better maneuvering during the insertion.

A fourth advantage relates to the “fit” of the hearing aid device within the auditory canal. The relative reduced hardness, e.g. flexibility of part or parts of the casing, enables the casing device of the present embodiments to fit firmly within the auditory canal, and conforming to changes in the canal, for example increase or reduction in size due to illness, diet, and/or hormonal changes.

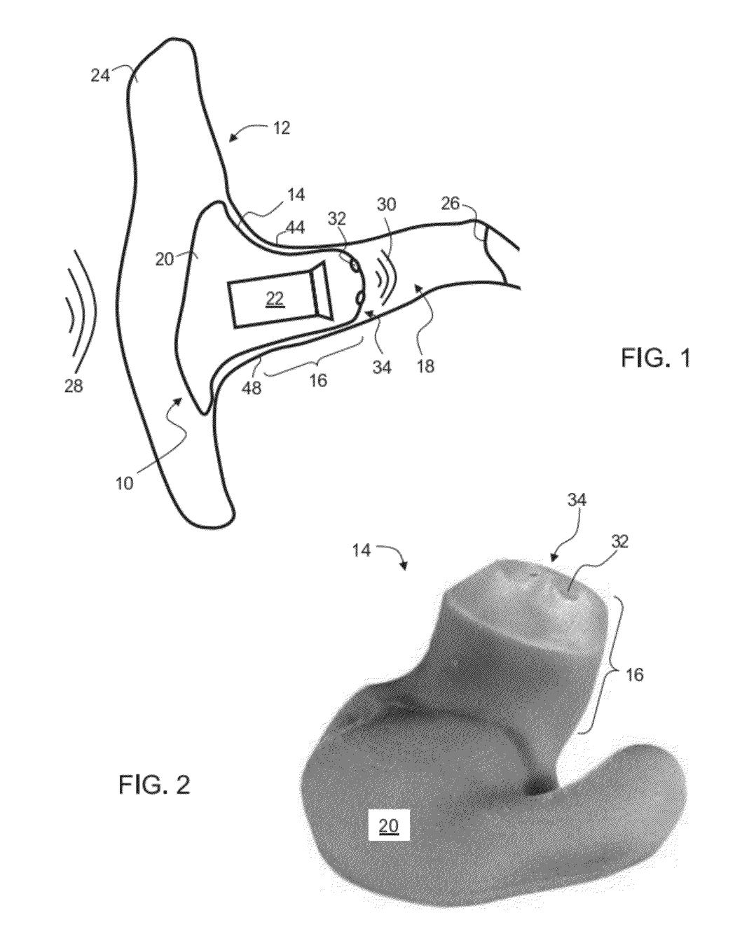

Referring now to the drawings, FIG. 1 is a schematic illustration of a cross-sectional view of an ear 12 and a hearing aid device 10 placed therein according to some exemplary embodiments of the present invention.

Hearing aid device 10 is preferably implemented as an In-The-Ear (ITE) hearing aid device, but may optionally be implemented as an In-The-Canal (ITC) or Completely-In-The-Canal (CIC) hearing aid device. Embodiments in which hearing aid device 10 is implemented as a Behind-The-Ear (BTE) hearing aid device are not excluded, but are somewhat less preferred. The differences between ITE, ITC, CIC and BTE hearing aid device are known to those skilled in the art of hearing aids. Briefly, an ITE hearing aid device is partially introduced into the ear such that part of the device is visible to a third party, an ITC hearing aid device is introduced almost completely into the auditory canal and is therefore less visible to a third party (e.g., visible only upon direct gaze into the ear of the wearer), a CIC hearing aid device is introduced completely into the auditory canal and is therefore not visible or visible only upon close inspection, and a BTE hearing aid device is mounted behind the pinna of the wearer's ear and is quite visible to third parties. FIG. 1 is a schematic illustration of hearing aid device 10 in an embodiment in which it is implemented as an ITE hearing aid device. Other implementations are not shown for brevity, but the ordinarily skilled person, provided with the details described herein, would know how to adjust the hearing aid device for other implementations.

Ear 12 is illustrated in an orientation corresponding to an upright orientation of the head (e.g., when the wearer of device 10 is standing or sitting). Below, the terms “upper” and “lower” are used to indicate relative positions of sectional regions of the ear, relative to gravity, when the head of the wearer is in the upright position. Thus, for example, when the head is in the upright position a surface 44 of the auditory canal 18 of ear 12, is upper with respect to the cavity of the canal and a surface 48 of canal 18 is lower with respect to the cavity of the canal.

Hearing aid device 10 comprises a casing device 14 having an elongated extension 16 adapted to at least partially fit within the auditory canal 18 of ear 12. Casing device 14 can also comprise a base section 20 from which elongated extension 16 extends. The elongated extension preferably integrally extends from the base section, namely the casing device is devoid of any assembling elements, and the “regions” of the casing device cannot be disassembled from each other without rupturing or use of a cutting instrument. In a preferred embodiment of the invention, casing 14 is fabricated by SFF in its entirety, e.g., in a single fabrication process.

Hearing aid device 10 also comprises a miniaturized electroacoustic device 22 encapsulated within casing device 14. Electroacoustic device 22 serves for receiving acoustic waves 28 reaching ear 12 (e.g., by entering the pinna 24), converting the acoustic waves to electrical signals, amplifying the signals and converting the amplified signals back into amplified acoustic waves 30 propagating in the direction of the eardrum 26. Miniaturized electroacoustic devices are known in the art. Miniaturized electroacoustic devices suitable for the present embodiments are found, e.g., in U.S. Pat. Nos. 5,390,254, 5,987,146 and 6,914,994, and U.S. Published Application No. 20070076913, the contents of which are hereby incorporated by reference.

Optionally and preferably casing device 14 comprises one or more openings 32, e.g., at a tip 34 of elongated extension 16, for venting and/or acoustic impedance matching, as known in the art of hearing aids. Other locations for the openings 32 are not excluded from the scope of the present invention.

An image of a perspective view of casing device 14 is shown in FIG. 2. The casing device shown in FIG. 2 was fabricated according to some embodiments of the present invention by three-dimensional printing technique. The printing technique included use of a three-dimensional printing system marketed by Objet Geometries Inc., Massachusetts, U.S.A., under the trade name Connex™, using two modeling materials marketed under the trade names FullCure680™ (semitransparent color in FIG. 2) and FullCure930™ (opaque color in FIG. 2).

The representative example of FIG. 2 shows an embodiment of the present invention in which the frontal section at tip 34 of elongated extension 16 is characterized by a reduced hardness, e.g. fabricated using a soft, flexible material, compared to all other sections of casing device 14. When casing device 14 includes more than two regions distinguishable by their hardness, the frontal section at tip 34 is optionally and preferably characterized by a reduced hardness, e.g. fabricated using a soft, flexible material, compared to at least one other section of casing device 14. Other configurations are not excluded from the scope of the present invention. Some representative examples of such configurations will now be described.

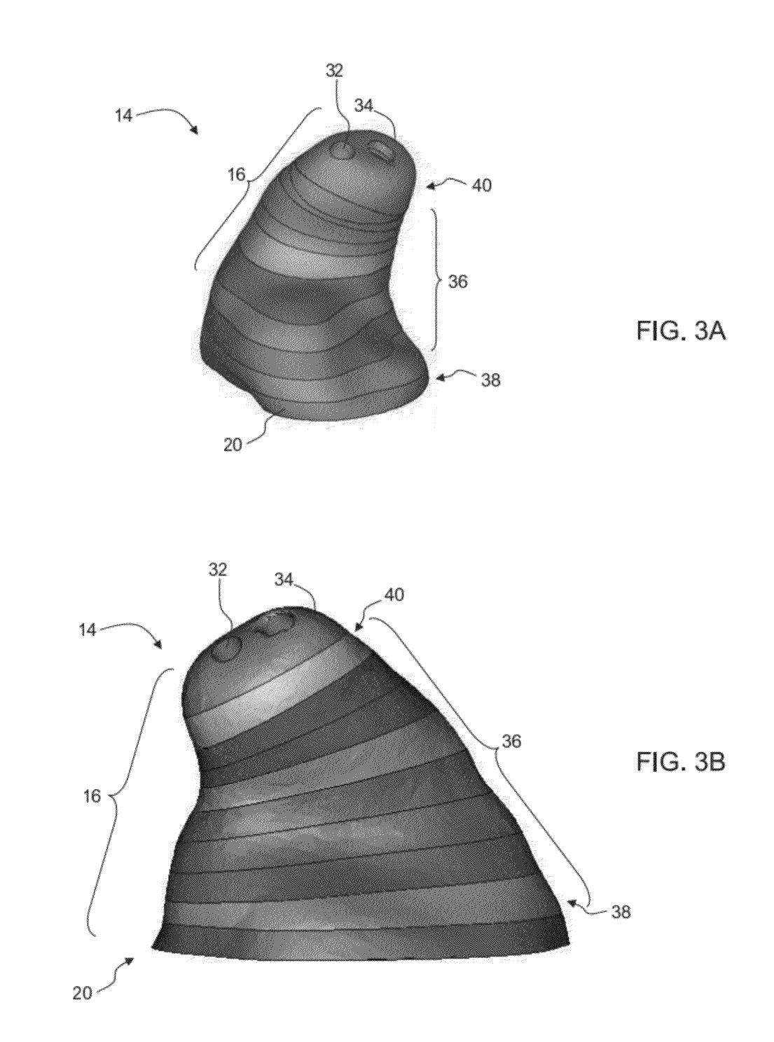

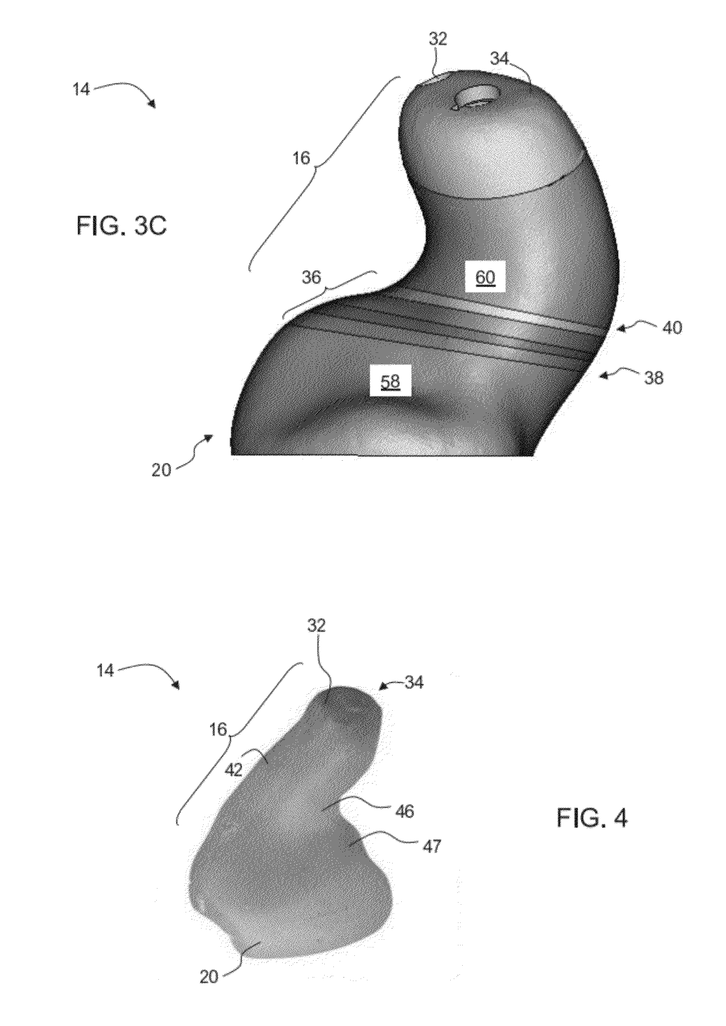

FIGS. 3A-C illustrate casing device 14 in embodiments of the invention in which the casing comprises a gradient region 36 between at least two regions 38 and 40. Gradient region 36 is characterized by a gradually increasing hardness. The gradual increment in the hardness is illustrated in FIGS. 3A-C as annular regions of different colors or grey levels.

The term “gradient region” as used herein refers to a region in which there is a continuous or step-wise change in the hardness of the material, wherein the charge is not necessarily linear and not necessarily monotonic. In various exemplary embodiments of the invention a gradient region includes at least three or at least four or at least five different hardness units, extending over a section whose length is less than 3 cm or less than 2 cm, e.g., 1 cm or less.

In the representative example of FIG. 3A, which is not intended to limit the scope of the present invention, gradient region 36 extends from base 20 to tip 34 of elongated extension 16. In this configuration, the hardness at tip 34 is preferably reduced compared to the hardness of base 20, and the hardness of gradient region 36 varies from higher values near base 20 to lower values near tip 20. Alternatively, the hardness of base 20 can be reduced compared to the hardness at tip 34, in which case the hardness of gradient region 36 varies from lower values near base 20 to higher values near tip 34.

In the representative example of FIG. 3B, which is also not intended to limit the scope of the present invention, gradient region 36 extends over a section of elongated extension 16 which does not necessarily includes base 20.

In the representative example of FIG. 3C, which is also not intended to limit the scope of the present invention, gradient region 36 forms a central section within casing device 14. The central section is shown as part of elongated extension 16 but may be located also at other parts of casing device 14. Preferably, but not necessarily, the parts 58, 60 of casing device 14 immediately adjacent to gradient region 36 are characterized by elevated hardness compared to the hardness of at least a portion of gradient region 36. For example, the hardness at part 58 which immediately adjacent to region 38 can be higher than the hardness at region 38, and the hardness at part 60 which immediately adjacent to region 40 can be higher than the hardness at region 40. Alternatively, the hardness at part 58 can be the same as the hardness at region 38, and the hardness at part 60 can be higher than the hardness at region 40.

It is to be understood that FIGS. 3A-C are exemplary embodiments only and that it is not necessary for gradient region 36 to be between base 20 and tip 34. The present inventor contemplates embodiments in which gradient region 36 may extend between any two regions of different hardness along any tangential or thickness direction across casing device 14. Furthermore, casing device 14 can comprise two or more gradient regions or it may be devoid of gradient regions.

The change in hardness within gradient region 36 can be, for example, from about 20 hardness unit to about 150 hardness units over the entire length of region 36. When region 36 extends from base 20 to tip 34, the change in hardness within gradient region 36 is optionally and preferably from about 20 hardness unit to about 150 hardness units over the entire length elongated extension 16. In some embodiments of the invention, the rate of change in hardness within gradient region 36 is from about 20 hardness units per cm to about 50 hardness units per cm.

The advantage of the embodiments in which casing device 14 has one or more gradient region is that they allow meeting specific hearing-aid design requirements, as well as individual user needs, e.g., needs related to specific ear canal anatomies. Such fine-tuning of the hardness across the casing device has heretofore been impractical or too expensive, and the present disclosure makes such configuration feasible and practical from standpoints of both cost and manufacturing complexity.

FIG. 4 is an image of casing device 14 manufactured according to an embodiment of the invention in which casing device 14 has an upper contact section 42 at an upper part of elongated extension 16 to engage an upper surface of auditory canal 18 (not shown see surface 44 in FIG. 1), wherein upper contact section 42 has a reduced hardness compared to at least one other region of elongated extension. The casing device in FIG. 4 was fabricated using the same three-dimensional printing system and modeling materials as the casing device shown in FIG. 2, except that the printing system was configured for gradually varying the combination between the two modeling materials so as to form gradient regions across the casing. In FIG. 4, regions of reduced hardness are shown in darker colors. Thus, for example, the hardness of base 20, which is shown in a brighter color, is higher than the hardness of upper contact section 42 which is shown in a darker color. Another section of elevated hardness is shown at the lower part 46 of elongated extension 16. This section serves as a lower contact section for engaging a lower surface of auditory canal 18 (not shown see surface 48 in FIG. 1). Section 46 can be used to support and protect the electronic circuitry and/or power source within casing device 14.

The region between section 42 and section 46 serves as a gradient region since the hardness gradually increases from section 42 to section 46. This gradual change in hardness is shown as a gradual change of color from a darker color near section 42 to a brighter color near section 46. In some embodiments of the present invention casing device 14 also comprises a generally annular section 47 immediately adjacent to section 46, between section 46 and base 20. Section 47 preferably extends over the entire perimeter of elongated extension 16 between section 46 and base 20, but may also extend only over part of the perimeter, if desired. Section 47 has a reduced hardness compared to section 46. Optionally and preferably, section 47 has a reduced hardness compared to both section 46 and base 20. The advantage of having an annular section of reduced hardness is that it increases the comfort of the wearer of the hearing aid device.

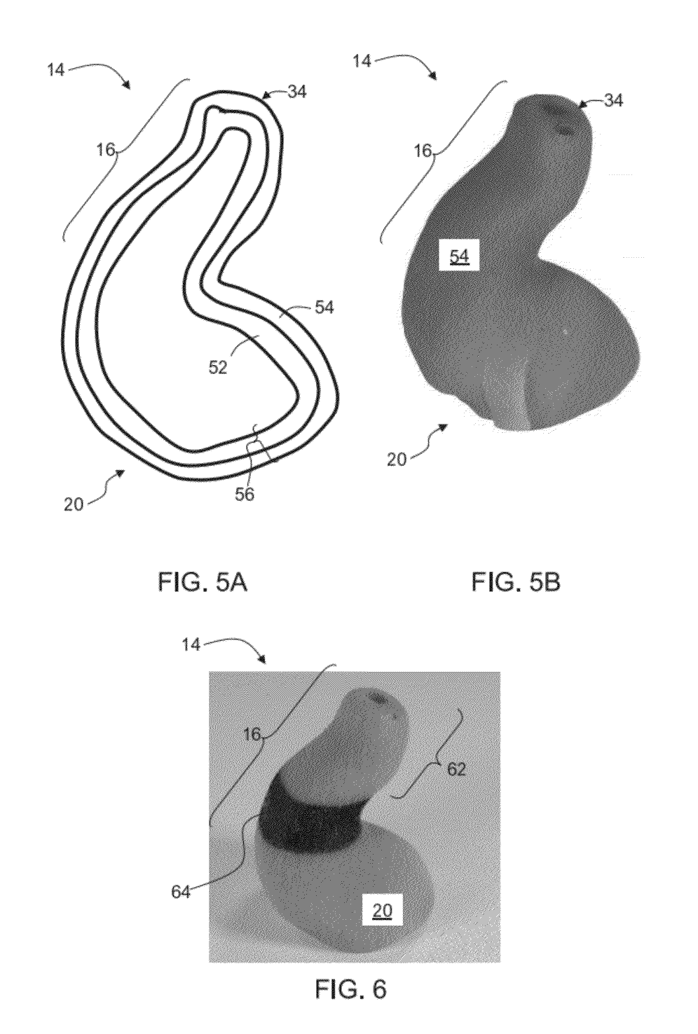

FIGS. 5A-B are a schematic illustration of a cross-sectional view (FIG. 5A) and an image of a perspective view (FIG. 5B) of casing device 14 manufactured according to an embodiment of the invention in which casing device 14 has an inner layer 52 (not shown in image 5B) and an outer contact layer 54 covering inner layer 52. Layers 52 and 54 form a layered structure across the thickness direction of wall 56 of device 14. Outer contact layer 54 preferably has a reduced hardness compared to inner layer 52. This embodiment is useful, for example, when it is desired to have a hearing aid device that is generally rigid, but with less potentially irritating surfaces of contact between the device and the ear's tissue. The casing device 14 shown image 5B was fabricated using the same three-dimensional printing system and modeling materials used for the casing device shown in FIG. 2 except that the three-dimensional printing machine was configured to fabricate the inner layer from the Skin Tone FullCure®680 modeling material, and the outer layer from the Tango Plus FullCure®930 modeling material (Objet Geometries Ltd.).

FIG. 6 is an image showing a perspective view of casing device 14 manufactured according to an embodiment of the invention in which casing device 14 has a frontal section 62 at a frontal part of elongated extension 16, and an intermediate section 64 between frontal section 62 and base section 20. Intermediate section 64 optionally and preferably has a reduced hardness compared to both frontal section 62 and base section 20. The advantage of these embodiments is that it allows better affixation of casing device 14 within the ear of the wearer, and flexibility of the casing particularly during events of relative motions between, e.g., the outer ear and the auditory canal, for example, during talking, chewing, yawning or teeth clenching. Thus, intermediate section 64 preferably serves as a flexible connective section while frontal section 64 is fixed within the canal and base 20 is fixed in the outer ear. When there is relative motion between the auditory canal and the outer ear, both sections 64 and 20 remain well affixed in their respective locations due to the flexibility of connective section 64.

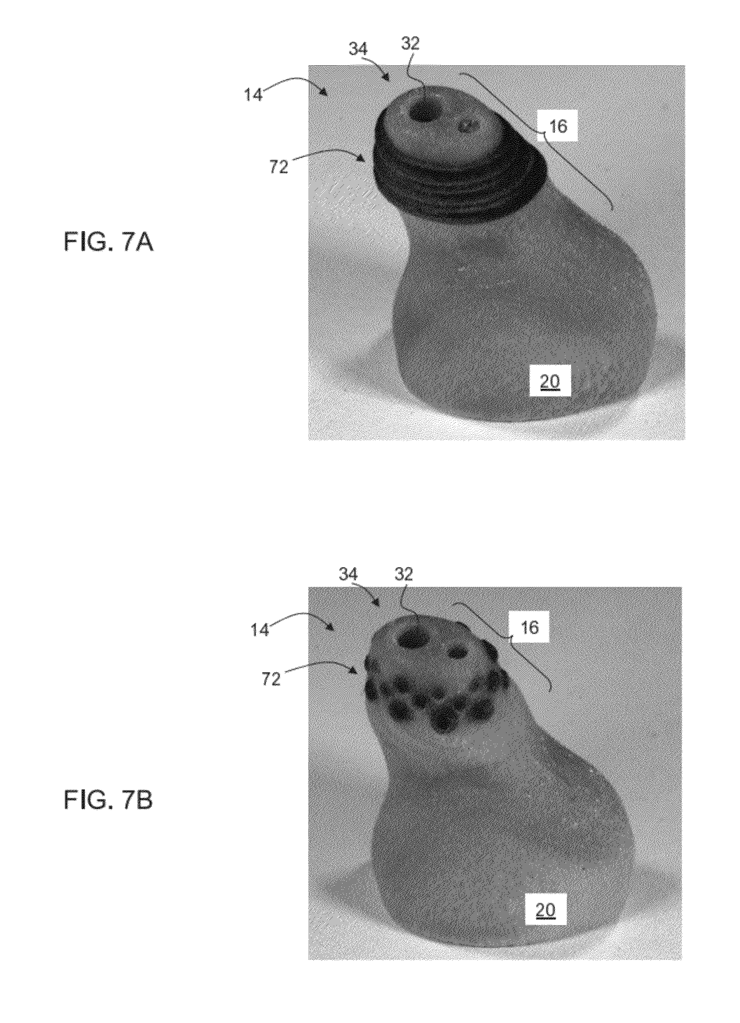

FIGS. 7A-B are images showing a perspective view of casing device 14 manufactured according to an embodiment of the invention in which casing device 14 has a flexible relief 72 pattern at tip 34 of elongated extension 16.

Pattern 72 can be of any shape. For example, pattern 72 can comprise one or more rings wound around elongated extension 16, as shown in FIG. 7A, or a plurality of protuberances, as illustrated in FIG. 7B. The advantage of this embodiment is that it further enhances affixation of elongated extension 16 within the auditory canal. The flexibility of pattern 72 provides tip 34 with a self-adapting property. In use, elongated extension 16 is introduced into the auditory canal such that pattern 72 is pressed against the inner surface of the canal. When the shape of the auditory canal experiences slight changes, e.g., over time or due to a change in the condition of the wearer (e.g., change of temperature, etc.) pattern 72 adapts itself to the new geometry by virtue of its flexibility.

The casing devices 14 shown in images 7A-B were fabricated using the same three-dimensional printing system and modeling materials used for the casing device shown in FIG. 2, except for the placing of the materials. In FIG. 2, the tip 34 of casing device 14 is made of a material having reduced hardness compared to the other parts of casing device 14, and in FIGS. 7A-B pattern 72 is made of the material having reduced hardness compared to tip 34. For fabricating the casing devices 14 shown in images 7A-B the three-dimensional printing machine was configured to fabricate pattern 72 from the Tango Plus FullCure®930 modeling material, and the other sections of casing device 14 from the Skin Tone FullCure®680 modeling material.

It is expected that during the life of a patent maturing from this application many relevant solid freeform fabrication techniques will be developed and the scope of the term solid freeform fabrication is intended to include all such new technologies a priori.

As used herein the term “about” refers to ±10%.

The word “exemplary” is used herein to mean “serving as an example, instance or illustration.” Any embodiment described as “exemplary” is not necessarily to be construed as preferred or advantageous over other embodiments and/or to exclude the incorporation of features from other embodiments.

The word “optionally” is used herein to mean “is provided in some embodiments and not provided in other embodiments.” Any particular embodiment of the invention may include a plurality of “optional” features unless such features conflict.

The terms “comprises”, “comprising”, “includes”, “including”, “having” and their conjugates mean “including but not limited to”.

The term “consisting of” means “including and limited to”.

The term “consisting essentially of” means that the composition, method or structure may include additional ingredients, steps and/or parts, but only if the additional ingredients, steps and/or parts do not materially alter the basic and novel characteristics of the claimed composition, method or structure.

As used herein, the singular form “a”, “an” and “the” include plural references unless the context clearly dictates otherwise. For example, the term “a compound” or “at least one compound” may include a plurality of compounds, including mixtures thereof.

Throughout this application, various embodiments of this invention may be presented in a range format. It should be understood that the description in range format is merely for convenience and brevity and should not be construed as an inflexible limitation on the scope of the invention. Accordingly, the description of a range should be considered to have specifically disclosed all the possible sub-ranges as well as individual numerical values within that range. For example, description of a range such as from 1 to 6 should be considered to have specifically disclosed sub-ranges such as from 1 to 3, from 1 to 4, from 1 to 5, from 2 to 4, from 2 to 6, from 3 to 6 etc., as well as individual numbers within that range, for example, 1, 2, 3, 4, 5, and 6. This applies regardless of the breadth of the range.

Whenever a numerical range is indicated herein, it is meant to include any cited numeral (fractional or integral) within the indicated range. The phrases “ranging/ranges between” a first indicate number and a second indicate number and “ranging/ranges from” a first indicate number “to” a second indicate number are used herein interchangeably and are meant to include the first and second indicated numbers and all the fractional and integral numerals therebetween.

It is appreciated that certain features of the invention, which are, for clarity, described in the context of separate embodiments, may also be provided in combination in a single embodiment. Conversely, various features of the invention, which are, for brevity, described in the context of a single embodiment, may also be provided separately or in any suitable subcombination or as suitable in any other described embodiment of the invention. Certain features described in the context of various embodiments are not to be considered essential features of those embodiments, unless the embodiment is inoperative without those elements.

Although the invention has been described in conjunction with specific embodiments thereof, it is evident that many alternatives, modifications and variations will be apparent to those skilled in the art. Accordingly, it is intended to embrace all such alternatives, modifications and variations that fall within the spirit and broad scope of the appended claims.

All publications, patents and patent applications mentioned in this specification are herein incorporated in their entirety by reference into the specification, to the same extent as if each individual publication, patent or patent application was specifically and individually indicated to be incorporated herein by reference. In addition, citation or identification of any reference in this application shall not be construed as an admission that such reference is available as prior art to the present invention. To the extent that section headings are used, they should not be construed as necessarily limiting.

1. A casing device for a hearing aid, comprising:
an elongated extension fabricated by three-dimensional inkjet printing and being adapted to fit within the auditory canal of a wearer, the casing device having at least two printed regions each being characterized by a different hardness, and being configured to receive and encapsulate an electroacoustic device.

2. The device according to claim 1, further comprising a gradient region between said at least two regions, said gradient region being characterized by a gradually increasing hardness.

3. The device according to claim 1, wherein said at least two regions comprise a frontal section at a tip of said elongated extension, said frontal section having a reduced hardness compared to at least one other region of said elongated extension.

4. The device according to claim 1, wherein said at least two regions comprise an upper contact section at an upper part of said elongated extension to engage an upper surface of said auditory canal, said upper contact section having a reduced hardness compared to at least one other region of said elongated extension.

5. The device according to claim 1, wherein said at least two regions comprise a base section from which said elongated extension is extending, said base section having an increased hardness compared to at least one other region of said elongated extension.

6. The device according to claim 1, wherein said at least two regions comprise an inner layer and an outer contact layer covering said inner layer, said outer contact layer having a reduced hardness compared to said inner layer.

7. The device according to claim 1, wherein said at least two regions comprise a frontal section at a frontal part of said elongated extension, a base section from which said elongated extension is extending and an intermediate section between said frontal section and said base section, said intermediate section having a reduced hardness compared to both said frontal section and said base section.

8. The device according to claim 1, further comprising a flexible relief pattern at a tip of said elongated extension.

9-11. (canceled)

12. The device according to claim 1, comprising at least one region made of a flexible material.

13. A hearing aid device, comprising a casing device according to claims 1, and an electroacoustic device encapsulated by said casing device.

14. A method of improving hearing of a hearing impaired individual, comprising introducing at least one hearing aid device to at least one of the ears of the individual, wherein said at least one hearing aid device comprises the hearing aid device of claim 13.

15. A method of manufacturing a hearing aid device, comprising encapsulating an electroacoustic device within the casing device of claim 1.

16. A method of fabricating a casing of a hearing aid device, comprising, using a three-dimensional inkjet printing apparatus and at least two building materials for fabricating a casing having an elongated extension adapted to fit within the auditory canal of a wearer, wherein said fabricating comprises forming at least two regions each being characterized by a different hardness.

17. (canceled)

18. The method according to claim 16, further comprising forming a gradient region between said at least two regions, said gradient region being characterized by a gradually increasing hardness.

19. The method according to claim 16, comprising forming a frontal section at a tip of said elongated extension, said frontal section having a reduced hardness compared to at least one other region of said elongated extension.

20. The method according to claim 16, comprising forming an upper contact section at an upper part of said elongated extension to engage an upper surface of said auditory canal, said upper contact section having a reduced hardness compared to at least one other region of said elongated extension.

21. The method according to claim 16, comprising forming a base section from which said elongated extension is extending, said base section having an increased hardness compared to at least one other region of said elongated extension.

22. The method according to claim 16, comprising forming an inner layer and an outer contact layer covering said inner layer, said outer contact layer having a reduced hardness compared to said inner layer.

23. The method according to claim 16, comprising forming a frontal section at a frontal part of said elongated extension, a base section from which said elongated extension is extending and an intermediate section between said frontal section and said base section, said intermediate section having a reduced hardness compared to both said frontal section and said base section.

24. The method according to claim 16, comprising forming a flexible relief pattern at a tip of said elongated extension.

25-27. (canceled)

28. The method according to claim 16, comprising forming at least one region made of a flexible material.

29. A method of manufacturing a hearing aid device, comprising:
fabricating a casing device using a method according to claim 16; and
encapsulating an electroacoustic device within said casing device.
